(19) United States
(12) Patent Application Publication
(10) Pub. No.: US 2024/0234260 A9
(43) Pub. Date: Jul. 11, 2024

(54) POWER SEMICONDUCTOR DEVICE

(71) Applicant: Mitsubishi Electric Corporation, Tokyo (JP)

(72) Inventors: Takuya SAKAMOTO, Tokyo (JP); Keitaro ICHIKAWA, Tokyo (JP); Yuji SHIKASHO, Tokyo (JP)

(73) Assignee: Mitsubishi Electric Corporation, Tokyo (JP)

(21) Appl. No.: 18/453,991

(22) Filed: Aug. 22, 2023

(30) Foreign Application Priority Data
Oct. 25, 2022 (JP) 2022-170355

(51) Int. Cl. H01L 23/495; H01L 23/00; H01L 23/31; H01L 25/07

(52) U.S. Cl. CPC H01L 23/4952; H01L 23/3135; H01L 23/49562; H01L 23/49575; H01L 24/48; H01L 25/072; H01L 2224/48245; H01L 2924/1815

(57) ABSTRACT

A power semiconductor device according to the present disclosure includes, in the following order, a conductor plate, an insulator, a lead frame, a first mold package including a plurality of semiconductor elements provided on the lead frame inside thereof, and resin-sealed such that a main surface of the conductor plate opposite to a side on which the insulator is provided is exposed, and a second mold package in which the first mold package is resin-sealed such that the main surface is exposed, in which the lead frame has a plurality of terminals protruding from one side surface of the first mold package, the plurality of terminals are projecting from a front surface of the second mold package opposite to the conductor plate, and the plurality of terminals are alternately arranged to form a staggered pattern closer to one side of the front surface in plan view.

### BACKGROUND OF THE INVENTION

### Field of the Invention

The present disclosure relates to a power semiconductor device, and more particularly to a power semiconductor device with a miniaturized package.

### Description of the Background Art

In a conventional power semiconductor device, for example, as disclosed in Japanese Patent Application Laid-Open No. 2014-120619, a configuration is adopted where a first semiconductor package in which a semiconductor element is sealed with a first resin is further sealed with a second resin, the tips of the terminals protrude from the upper surface of the second semiconductor package made of the second resin.

In the power semiconductor device disclosed in Japanese Patent Application Laid-Open No. 2014-120619, a plurality of terminals are arranged close to each other without being able to secure a sufficient inter-terminal creepage distance. There has been a problem where attempting to secure a sufficient inter-terminal creepage distance results in the enlargement of the package size.

### SUMMARY

An object of the present disclosure is to provide a power semiconductor device with a miniaturized package.

A power semiconductor device according to the present disclosure includes a conductor plate, an insulator mounted on the conductor plate, a lead frame mounted on the insulator, a first mold package including a plurality of semiconductor elements provided on the lead frame inside thereof, and resin-sealed such that a main surface of the conductor plate opposite to a side on which the insulator is provided is exposed, and a second mold package in which the first mold package is resin-sealed such that the main surface is exposed, in which the lead frame has a plurality of terminals protruding from one side surface of the first mold package, the plurality of terminals are bent inside the second mold package in a direction opposite to the main surface of the conductor plate, projecting from a front surface of the second mold package opposite to the conductor plate, and the plurality of terminals are alternately arranged to form a staggered pattern closer to one side of the front surface in plan view.

According to the power semiconductor device of the present disclosure, the plurality of terminals protrude from the front surface of the second mold package opposite to the main surface of the conductor plate, that allows a creepage distance from the conductor plate of the second mold package to the plurality of terminals to be extended. Also, the terminals are alternately arranged into a staggered pattern, that allows the inter-terminal creepage distance can be secured not only in the direction parallel to one side, that is the terminal extraction side, of the second mold package, but also in the direction perpendicular to the same. Therefore, the length in the direction parallel to one side of the second mold package can be made shorter than conventional packages, allowing securing the inter-terminal creepage distance while miniaturizing the outer shape of the second mold package, ensuring to seal a large power capacity semiconductor element.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view illustrating a terminal arrangement of a power semiconductor device according to Embodiment 1 of the present disclosure;

FIG. 2 is a cross-sectional view illustrating a configuration of the power semiconductor device according to Embodiment 1 of the present disclosure;

FIG. 3 is a cross-sectional view illustrating the configuration of the power semiconductor device according to Embodiment 1 of the present disclosure;

FIG. 4 is a cross-sectional view illustrating a method of manufacturing the power semiconductor device according to Embodiment 1 of the present disclosure;

FIG. 5 is a cross-sectional view illustrating the method of manufacturing the power semiconductor device according to Embodiment 1 of the present disclosure;

FIG. 6 is a plan view illustrating a terminal arrangement of a power semiconductor device according to Embodiment 2 of the present disclosure;

FIG. 7 is a plan view illustrating a terminal arrangement of a power semiconductor device according to Embodiment 3 of the present disclosure;

FIG. 8 is a plan view illustrating a terminal arrangement of a power semiconductor device according to Embodiment 4 of the present disclosure;

FIG. 9 is a cross-sectional view illustrating a configuration of the power semiconductor device according to Embodiment 4 of the present disclosure;

FIG. 10 is a cross-sectional view illustrating a configuration of a power semiconductor device according to Embodiment 5 of the present disclosure; and

FIG. 11 is a cross-sectional view illustrating a configuration of the power semiconductor device according to Embodiment 4 of the present disclosure.

### DESCRIPTION OF THE PREFERRED EMBODIMENTS

### Introduction

In the description, even though terms indicating specific positions and directions such as “up”, “low”, “side”, “front”, and “back” may be used, these terms are for promoting the understanding of the contents of Embodiments and are not related to the directions at the time of actual implementation.

It should be noted that the drawings are illustrated schematically, and the mutual relationship between the sizes and positions of the images illustrated in different drawings is not necessarily accurately illustrated and may be changed as appropriate. In addition, in the following description, the same components are denoted and illustrated by the same reference numerals, and the names and functions thereof are also the same. Accordingly, detailed descriptions thereof may be omitted.

### Embodiment 1

<Device Configuration>

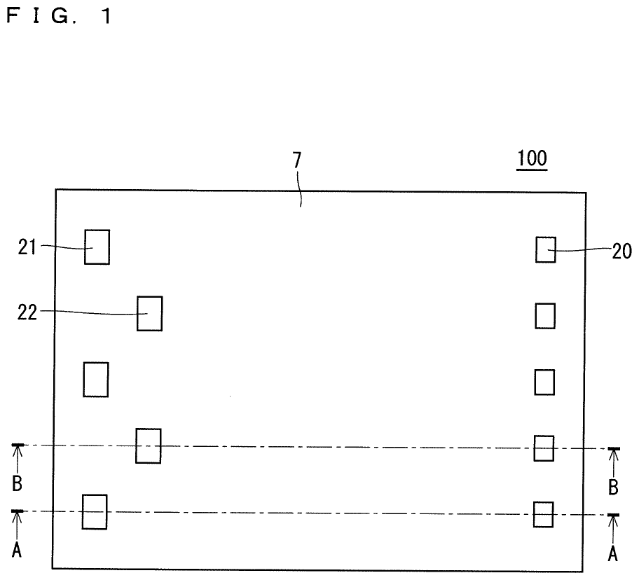

FIG. 1 is a plan view illustrating a terminal arrangement of a power semiconductor device 100 according to Embodiment 1 of the present disclosure, and is a plan view of the power semiconductor device 100 viewed from the upper surface side from which terminals protrude. As illustrated in FIG. 1, in the power semiconductor device 100, a plurality of terminals 21 (first terminals) and a plurality of terminals 22 (second terminals) are arranged in a staggered pattern at positions closer to one of the two shorter sides on the upper surface of a mold package 7 (second mold package) having a rectangular shape in plan view. Specifically, the terminals 21 and the terminals 22 are alternately arranged with the terminals 21 positioned closer to the outer side and the terminals 22 positioned closer to the inner side of the mold package 7. Also, a plurality of terminals 20 are arranged in a row along the shorter side at positions closer to an other of the two shorter sides.

In this manner, by arranging the terminals 21 and the terminals 22 in a staggered pattern, an inter-terminal creepage distance is secured not only in the direction parallel to the terminal extraction side but also in the direction perpendicular to the terminal extraction side of the mold package 7, shortening the length of the mold package 7 in the direction parallel to the terminal extraction side more than the conventional counterpart, thereby securing the inter-terminal creepage distance while miniaturizing the outer shape of the mold package 7.

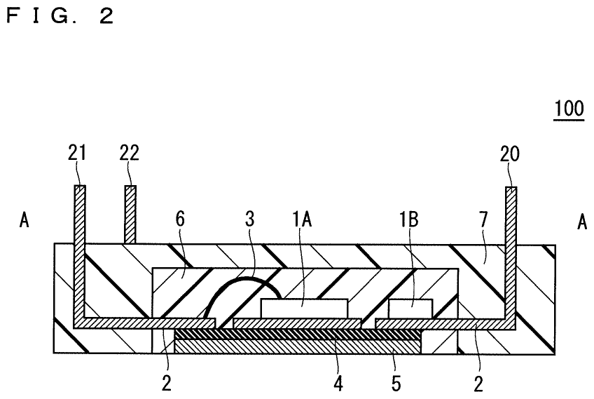

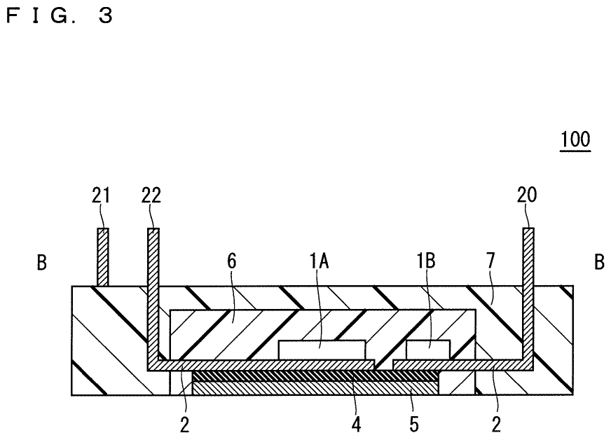

FIG. 2 is a cross-sectional view taken along line A-A in FIG. 1, and FIG. 3 is a cross-sectional view taken along line B-B in FIG. 1.

In FIG. 2, an insulator 4 is mounted on a conductor plate 5, and a lead frame 2 is mounted on the insulator 4. A semiconductor element 1A and a semiconductor element 1B are mounted on the lead frame 2. The semiconductor elements 1A and 1B have features required for the operation of power semiconductor device 100, and are connected to the lead frame 2 by soldering or the like.

The lead frame 2 is separated into a portion where the semiconductor element A is mounted and a portion where the semiconductor element 1B is mounted. And the portion where the semiconductor element 1B is mounted is integral with the terminal 20, which is bent perpendicularly toward the upper surface of mold package 7, with the tip thereof protruding from the upper surface of mold package 7.

Although the portion where the semiconductor element 1A is mounted is separated from the terminal 21, the upper surface electrode of the semiconductor element 1A is electrically connected to the terminal 21 vie a wire 3. The terminal 21 is vertically bent toward the upper surface of the mold package 7 with the tip thereof protruding from the upper surface of the mold package 7.

For the lead frame 2, a copper material having a thickness of, for example, 1 mm and having the flat upper and lower surfaces can be used. For the wire 3, a thin metal wire, for example, such as aluminum, can be used.

The insulator 4 desirably has high thermal conductivity. For example, an epoxy resin containing a high thermal conductivity filler can be used as the material.

The conductor plate 5 is integrally formed with the insulator 4, and the insulator and the conductor plate 5 have the same width and depth in plan view. Copper, aluminum, or the like can be used as the material of the conductor plate 5. The lower surface of the conductor plate 5 forms the same plane as the lower surface of the mold package 7.

Except for the lower surface of the conductor plate 5, the insulator 4, the lead frame 2, the wire 3, and the semiconductor elements 1A and 1B are sealed with a mold resin to form a mold package 6 (first mold package). Further, the power semiconductor device 100 adopts a transfer mold type package, with the outside, except for the lower surface of the mold package 6, being covered with the mold package 7.

The materials of the mold package 6 and the mold package 7 contain a thermosetting resin material, which are subjected to transfer molding to be formed; therefore, they are the materials having fluidity at the time of resin sealing. And the composition is set such that the temperature at which the resin of the mold package 6 melts is higher than the temperature at which the resin of the mold package 7 melts.

The tips of the terminals 20 to 22 protrude from the upper surface of the package, and the structure is that the terminals 20 to 22 are sealed with the resin forming the mold package 7 except for the protruding portions.

The number, thickness, tip shape, etc. of the terminals 20 to 22 are not particularly limited. Although the volume of the package is not particularly limited as long as the mold package 6 except for the lower surface and the terminals 20 to 22 other than the portions protruding from the upper surface can be sealed, from the viewpoint of miniaturization, the smaller it can be, the more desirable.

When the power semiconductor device 100 is mounted on the heat sink or the like for heat radiation, the conductor plate 5 comes into contact with the heat sink, which makes it desirable that the entire lower surface of the conductor plate 5 is exposed.

The cross-sectional structure illustrated in FIG. 3 is basically the same as FIG. 2, however, in the cross section of FIG. 3, the portion where the semiconductor element 1A is mounted is integrated with the terminal 22, and the terminal 22 is vertically bent toward the upper surface of the mold package 7 with the tip thereof protruding from the upper surface of the mold package 7. In this manner, the terminals 21 and 22 are individually connected to the semiconductor element 1A, differences in electric energy occur among the terminals, hence, the terminals are arranged in a staggered pattern so as to secure an inter-terminal creepage distance to be required due to the differences in electric energy. Therefore, by arranging the terminals 21 and 22 in a staggered pattern as illustrated in FIG. 1, the inter-terminal creepage distance can be secured and the outer shape of the mold package 7 can be miniaturized.

Although in the present disclosure, a transfer mold type package illustrated in FIGS. 2 and 3 has been described, the structure of FIGS. 2 and 3 is an example, and the present disclosure can be applied to packages of other structures as long as being a transfer mold type.

Although in the present disclosure, the configuration has been illustrated in which the lower surfaces of the semiconductor elements 1A and 1B are bonded to the lead frames 2 by soldering or the like, the present disclosure is also applicable to a configuration in which both surfaces of the semiconductor elements are bonded to the lead frames by soldering or the like.

<Manufacturing Method>

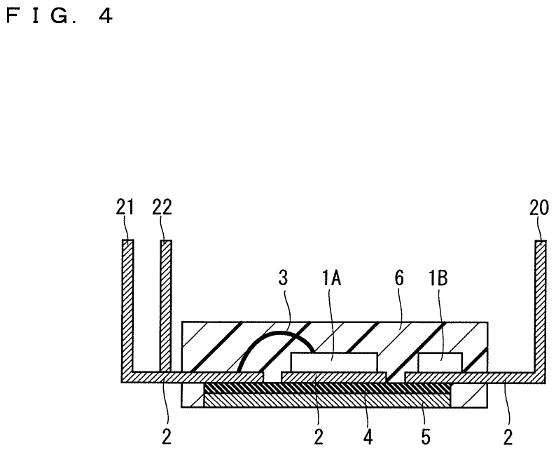

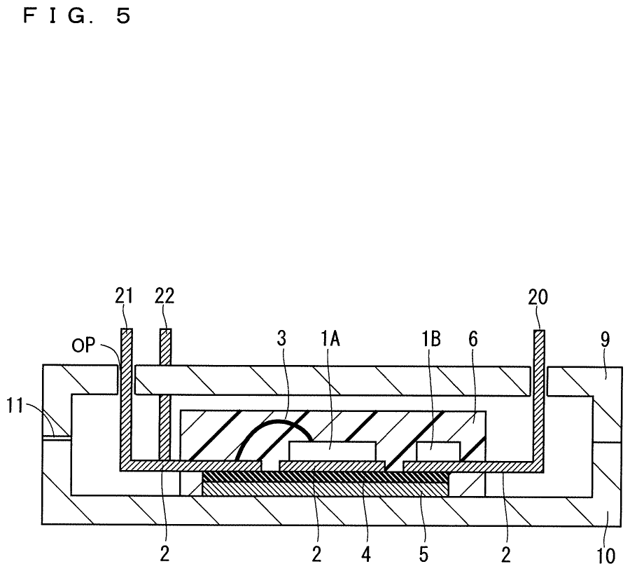

Next, a method of manufacturing the power semiconductor device 100 will be described with reference to FIGS. 4 and 5. FIG. 4 is a cross-sectional view illustrating the mold package 6 sealed with a resin, and is a cross-sectional view corresponding to FIG. 2.

In FIG. 4, the lead frame 2 is mounted on the insulator 4 integrated with the conductor plate 5, and the semiconductor elements 1A and 1B are bonded to the lead frame 2 by soldering or the like. The semiconductor element 1A is electrically connected to the lead frame 2 integrated with the terminal 21 through the wire 3.

These are sealed with the resin, and the lead frame 2 integrated with the terminal and the lead frame 2 integrated with the terminal 21 protrude horizontally, that is, in a direction parallel to the lower surface of conductive plate 5 from the two opposing side surfaces of mold package 6. The lead frame 2 is bent at a certain point in the vertical direction, that is, in a direction orthogonal to the lower surface of the conductor plate 5, and the tip is positioned higher than the upper surface of the mold package 6.

FIG. 5 is an example of a cross-sectional view illustrating a state in which the mold package 6 sealed with a resin is put into a sealing mold.

In FIG. 5, the sealing mold is composed of an upper mold 9 and a lower mold 10. The upper mold 9 has a plurality of openings OP into which the terminals 20 to 22 are inserted while the power semiconductor device 100 is placed in the lower mold 10 and the upper mold 9 is covered. The plurality of openings OP are formed in accordance with the arrangement pattern of the terminals 20 to 22, and are formed in such a size that there is almost no gap when the terminals 20 to 22 are inserted into each of them. Therefore, when the resin material forming the mold package 7 is injected into the sealing mold, the resin material does not enter the openings OP, and the resin material does not adhere to the surfaces of the terminals 20 to 22.

The sealing process as follows: heating the upper mold 9 and the lower mold 10 with the upper mold 9 and the lower mold 10 stacking each other, heating and melting the sealing resin to a low viscosity state, injecting the sealing resin into the cavity formed by the upper mold 9 and the lower mold 10 through a runner 11 provided to extend through the side surface of the sealing mold, and allowing the sealing resin to undergo a curing reaction while maintaining pressure after the filling is completed.

As described earlier, the temperature at which the resin of the mold package 6 melts is higher than the temperature at which the resin of the mold package 7 melts; therefore, the sealing resin is heated and melted at a temperature at which the mold package 6 does not melt. Through the above process, the power semiconductor device illustrated in FIGS. 1 to 3 can be obtained.

### Embodiment 2

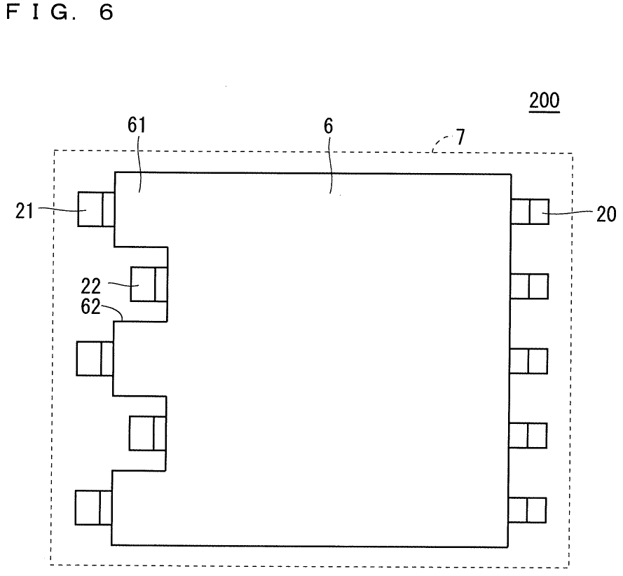

FIG. 6 is a plan view illustrating a terminal arrangement of a power semiconductor device 200 according to Embodiment 2 of the present disclosure, and is a plan view of the power semiconductor device 200 viewed from the upper surface side from which terminals protrude. In FIG. 6, the mold package 7 is indicated by the broken line for the sake of convenience, and only the mold package 6 is indicated by the solid line. As illustrated in FIG. 6, the mold package 6 of the power semiconductor device 200 has a concave/convex shape being a concave/convex pattern, which lies along the staggered pattern in which the terminals 21 and 21 are arranged, on the side surface on which the terminals 21 and 22 protrude.

Specifically, portions from which the terminals 21 protrude are convex portions 61, and portions from which the terminals 22 protrude are concave portions 62 in each of which the side surface is recessed inwardly from the convex portion 61, and the convex portions 61 and the concave portions 62 are provided alternately.

The terminal 21 horizontally protruding from the convex portion 61 is vertically bent at a certain point toward the upper surface of the mold package 7.

The side surface of the mold package 6 from which the terminals 20 protrude is flat, the terminal 20 horizontally protruding from the flat side surface is vertically bent at a certain point toward the upper surface of the mold package 7, and a plurality of terminals 20 are arranged in a row along the short side of the mold package 7.

In this manner, by arranging the terminals 21 and the terminals 22 in a staggered pattern by making them protrude from the side surfaces of the convex portions 61 and the concave portions 62 provided on the side surface of the mold package 6, an inter-terminal creepage distance is secured not only in the direction parallel to the terminal extraction side but also in the direction perpendicular to the terminal extraction side of the mold package 7, shortening the length of the mold package 7 in the direction parallel to the terminal extraction side more than the conventional counterpart, thereby securing the inter-terminal creepage distance while miniaturizing the outer shape of the mold package 7.

In addition, by providing the convex portions 61 a space inside the mold package 6 is secured, achieving diversity in the arrangement of the lead frame 2 and the wires 3 inside.

Also, the terminal 22 arranged in the concave portion 62 is provided so as to be accommodated in the concave portion 62 in plan view; therefore, the surrounding thereof is protected by the concave portion 62, and defects, in the terminal bending process, and the transport process such as deformation of the terminals 22 occurring due to transport errors, can be suppressed.

The method of manufacturing the power semiconductor device 200 is the same as the method of manufacturing the power semiconductor device 100 described with reference to FIGS. 4 and 5, that is, it is put into the sealing mold and sealed with a resin.

Consequently, as in Embodiment 1, the configuration is achieved in which a plurality of terminals 21 and terminals 22 are arranged in a staggered pattern at positions closer to one of the two shorter sides on the upper surface of a mold package 7 having a rectangular shape in plan view.

### Embodiment 3

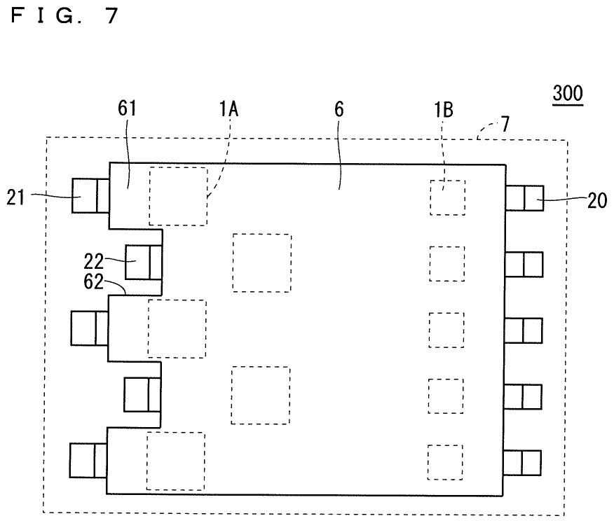

FIG. 7 is a plan view illustrating a terminal arrangement of a power semiconductor device 300 according to Embodiment 3 of the present disclosure, and is a plan view of the power semiconductor device 300 viewed from the upper surface side from which terminals protrude. In FIG. 7, the mold package 7 is indicated by the broken line for the sake of convenience, and only the mold package 6 is indicated by the solid line. As illustrated in FIG. 7, as in Embodiment 2, the mold package 6 of the power semiconductor device 300 has a concave/convex shape, which lies along the staggered pattern in which the terminals 21 and 21 are arranged, on the side surface on which the terminals 21 and 22 protrude.

Specifically, portions from which the terminals 21 protrude are convex portions 61, and portions from which the terminals 22 protrude are concave portions 62 in each of which the side surface is recessed inwardly from the convex portion 61, and the convex portions 61 and the concave portions 62 are provided alternately.

The terminal 21 horizontally protruding from the convex portion 61 is vertically bent at a certain point toward the upper surface of the mold package 7.

The side surface of the mold package 6 from which the terminals 20 protrude is flat, the terminal 20 horizontally protruding from the flat side surface is vertically bent at a certain point toward the upper surface of the mold package 7, and a plurality of terminals 20 are arranged in a row along the short side of the mold package 7.

In this manner, by arranging the terminals 21 and the terminals 22 in a staggered pattern by making them protrude from the side surfaces of the convex portions 61 and the concave portions 62 provided on the side surface of the mold package 6, an inter-terminal creepage distance is secured not only in the direction parallel to the terminal extraction side but also in the direction perpendicular to the terminal extraction side of the mold package 7, shortening the length of the mold package 7 in the direction parallel to the terminal extraction side more than the conventional counterpart, thereby securing the inter-terminal creepage distance while miniaturizing the outer shape of the mold package 7.

In addition, not only the terminals 21 and 22 are arranged in a staggered pattern but the semiconductor elements 1A arranged inside the mold package 6 are also arranged in a staggered pattern. Specifically, the semiconductor element 1A electrically connected to the terminal 21 is arranged at a position closer to the convex portion 61, and the semiconductor element 1A connected to the terminal 22 is arranged at a position recessed from the concave portion 62.

Also, the semiconductor elements 1B connected to a plurality of terminals 20 are arranged in a row along the short side of the mold package 6.

Thus, in the power semiconductor device 300 of Embodiment 3, by arranging the semiconductor elements 1A arranged inside the mold package 6 also in a staggered pattern, the distance between the semiconductor elements 1A in the direction parallel to terminal extraction side of the mold package 7 can be further reduced, so that the outer shape of the mold package 7 can be made even more miniaturized.

The method of manufacturing the power semiconductor device 300 is the same as the method of manufacturing the power semiconductor device 100 described with reference to FIGS. 4 and 5, that is, it is put into the sealing mold and sealed with a resin.

Consequently, as in Embodiment 1, the configuration is achieved in which a plurality of terminals 21 and terminals 22 are arranged in a staggered pattern at positions closer to one of the two shorter sides on the upper surface of a mold package 7 having a rectangular shape in plan view.

### Embodiment 4

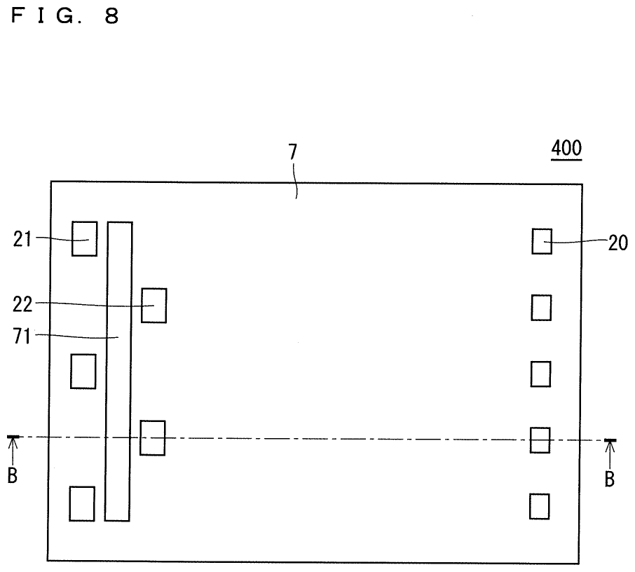

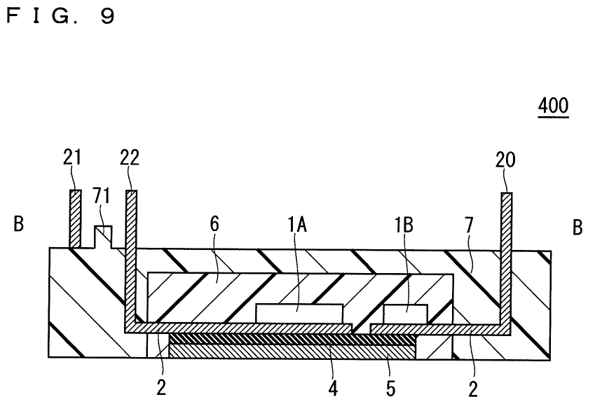

FIG. 8 is a plan view illustrating a terminal arrangement of a power semiconductor device 400 according to Embodiment 4 of the present disclosure, and is a plan view of the power semiconductor device 400 viewed from the upper surface side from which terminals protrude, and FIG. 9 is a cross-sectional view taken along line B-B in FIG. 8.

As illustrated in FIG. 8, although the power semiconductor device 400 is the same as the power semiconductor device 100 of Embodiment 1 in that the plurality of terminals 21 and 22 are arranged in a staggered pattern in plan view, the power semiconductor device 400 is provided with a protrusion 71 extending between the arrays of the terminals 21 and the terminals 22 in a direction parallel to both of the arrays of the terminals 21 and the terminals 22 arranged in a staggered pattern.

As illustrated in FIG. 9, by forming the protrusion 71 at the same time when the mold package 7 is formed, the protrusion 71 can be formed integrally with the mold package 7. By providing the protrusion 71, the creepage distance between the terminal and the terminal 22 can be further increased by the length, in cross section, of both side surfaces and the upper surface of the projecting portion 71, allowing a more large power capacity power semiconductor device 400 and the mold package 7 with its outer shape miniaturized further. By providing the projection between the extracted terminals, the inter-terminal creepage distance can be secured, increasing the amount of power.

Note that in FIG. 8, an example of one protrusion 71 integrated with the mold package 7 arranged between the array of the plurality of terminals 21 and the array of the plurality of terminals 22 has been illustrated, the shape, the number to be arranged, and the height of the projection can be arbitrarily set as long as the required inter-terminal creepage distance can be secured.

### Embodiment 5

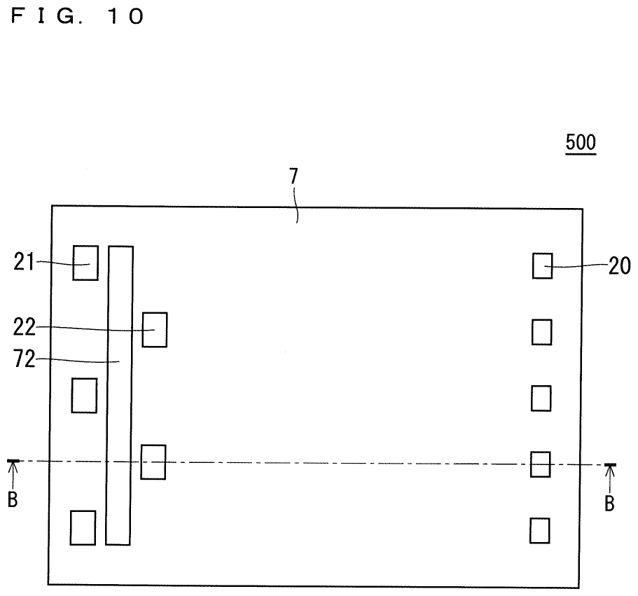

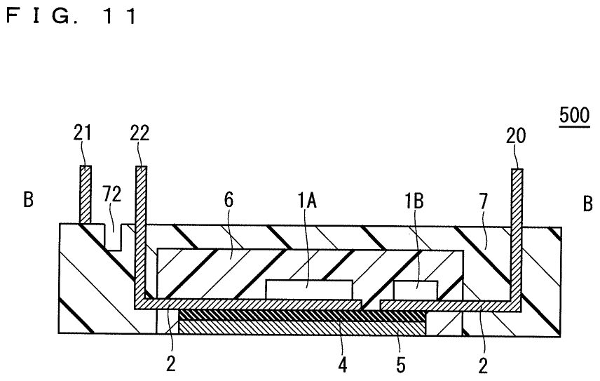

FIG. 10 is a plan view illustrating a terminal arrangement of a power semiconductor device 500 according to Embodiment 5 of the present disclosure, and is a plan view of the power semiconductor device 500 viewed from the upper surface side from which terminals protrude, and FIG. 11 is a cross-sectional view taken along line B-B in FIG. 9.

As illustrated in FIG. 10, although the power semiconductor device 500 is the same as the power semiconductor device 100 of Embodiment 1 in that the plurality of terminals 21 and 22 are arranged in a staggered pattern in plan view, the power semiconductor device 500 is provided with a groove-shaped recess 72 extending between the arrays of the terminals 21 and the terminals 22 in a direction parallel to both of the arrays of the terminals 21 and the terminals 22 arranged in a staggered pattern. The recess 72 can be formed at the same time when the mold package 7 is formed.

As illustrated in FIG. 11, by providing the recess 72, the creepage distance between the terminal 21 and the terminal 22 can be further increased by the length, in cross section, of both side surfaces and the upper surface of the projecting recess 72, allowing a more large power capacity power semiconductor device 500 and the mold package 7 with its outer shape miniaturized further.

Note that in FIG. 10, an example of one recess 72 arranged between the array of the plurality of terminals 21 and the array of the plurality of terminals 22 has been illustrated, the shape, the number to be arranged, and the depth of the recess can be arbitrarily set as long as the required inter-terminal creepage distance can be secured.

<Applicable Semiconductor Device>

Although the semiconductor materials of the semiconductor elements 1A and 1B are not particularly limited in Embodiments 1 to 5 described above, the semiconductor elements 1A and 1B may be silicon semiconductor elements using silicon (Si) as a semiconductor material, or may be silicon carbide semiconductor elements using silicon carbide (SiC) as a semiconductor material.

A switching element composed of SiC has a small switching loss and is capable of high-speed switching operation.

Switching elements composed of SiC have a low power loss and high heat resistance. Therefore, in case of a cooler such as a heat sink is provided, the radiation fins of the heat sink can be miniaturized; the size of the semiconductor module can be miniaturized.

Wide bandgap semiconductors other than SiC may be composed of gallium nitride-based materials, gallium oxide-based materials, diamond, or the like.

In the present disclosure, Embodiments of the present disclosure can be combined, appropriately modified or omitted, without departing from the scope of the disclosure.

The present disclosure described above will be collectively described as Appendices.

(Appendix 1)

A power semiconductor device comprising:
a conductor plate;
an insulator mounted on the conductor plate;
a lead frame mounted on the insulator;
a first mold package including a plurality of semiconductor elements provided on the lead frame inside thereof, and resin-sealed such that a main surface of the conductor plate opposite to a side on which the insulator is provided is exposed; and
a second mold package in which the first mold package is resin-sealed such that the main surface is exposed, wherein
the lead frame has a plurality of terminals protruding from one side surface of the first mold package,
the plurality of terminals are bent inside the second mold package in a direction opposite to the main surface of the conductor plate, projecting from a front surface of the second mold package opposite to the conductor plate, and
the plurality of terminals are alternately arranged to form a staggered pattern in a place closer to one side of the front surface in plan view.

(Appendix 2)

The power semiconductor device according to appendix 1, wherein
the plurality of terminals includes a plurality of first terminals and a plurality of second terminals,
the plurality of first terminals are arranged closer to the one side than the plurality of second terminals are in plan view, and
in the first mold package, the side surface from which the plurality of terminals protrude has concave/convex shape in which a portion from which each of the plurality of first terminal protrudes is a convex portion, and a portion from which each of the plurality of second terminals protrudes is a concave portion.

(Appendix 3)

The power semiconductor device according to appendix 2, wherein
each of the plurality of second terminals is provided so as to be accommodated in the concave portion in plan view.

(Appendix 4)

The power semiconductor device according to appendix 2 or 3, wherein
the plurality of semiconductor elements includes a plurality of first semiconductor elements electrically connected to the plurality of first terminals, respectively, and a plurality of second semiconductor elements electrically connected to the plurality of second terminals, respectively, and
the plurality of first semiconductor elements are arranged closer to the side surface of the first mold package than the plurality of second semiconductor elements are, and the plurality of semiconductor elements are alternately arranged to form a staggered pattern on the lead frame in plan view.

(Appendix 5)

The power semiconductor device according to appendix 1, wherein
the plurality of terminals includes a plurality of first terminals and a plurality of second terminals,
the plurality of first terminals are arranged closer to the one side than the plurality of second terminals are in plan view, and
the second mold package has a projection between an array of the plurality of first terminals and an array of the plurality of second terminals on the front surface, extending in a direction parallel to both arrays.

(Appendix 6)

The power semiconductor device according to appendix 1, wherein
the plurality of terminals includes a plurality of first terminals and a plurality of second terminals,
the plurality of first terminals are arranged closer to the one side than the plurality of second terminals are in plan view, and
the second mold package has a recess between an array of the plurality of first terminals and an array of the plurality of second terminals on the front surface, extending in a direction parallel to both arrays.

While the invention has been illustrated and described in detail, the foregoing description is in all aspects illustrative and not restrictive. It is therefore understood that numerous modifications and variations can be devised without departing from the scope of the invention.

What is claimed is:

1. A power semiconductor device comprising:
a conductor plate;
an insulator mounted on the conductor plate;
a lead frame mounted on the insulator;
a first mold package including a plurality of semiconductor elements provided on the lead frame inside thereof, and resin-sealed such that a main surface of the conductor plate opposite to a side on which the insulator is provided is exposed; and
a second mold package in which the first mold package is resin-sealed such that the main surface is exposed, wherein
the lead frame has a plurality of terminals protruding from one side surface of the first mold package,
the plurality of terminals are bent inside the second mold package in a direction opposite to the main surface of the conductor plate, projecting from a front surface of the second mold package opposite to the conductor plate, and
the plurality of terminals are alternately arranged to form a staggered pattern in a place closer to one side of the front surface in plan view.

2. The power semiconductor device according to claim 1, wherein
the plurality of terminals includes a plurality of first terminals and a plurality of second terminals,
the plurality of first terminals are arranged closer to the one side than the plurality of second terminals are in plan view, and
in the first mold package, the side surface from which the plurality of terminals protrude has concave/convex shape in which a portion from which each of the plurality of first terminal protrudes is a convex portion, and a portion from which each of the plurality of second terminals protrudes is a concave portion.

3. The power semiconductor device according to claim 2, wherein
the plurality of semiconductor elements includes a plurality of first semiconductor elements electrically connected to the plurality of first terminals, respectively, and a plurality of second semiconductor elements electrically connected to the plurality of second terminals, respectively, and
the plurality of first semiconductor elements are arranged closer to the side surface of the first mold package than the plurality of second semiconductor elements are, and the plurality of semiconductor elements are alternately arranged to form a staggered pattern on the lead frame in plan view.

4. The power semiconductor device according to claim 2, wherein
each of the plurality of second terminals is provided so as to be accommodated in the concave portion in plan view.

5. The power semiconductor device according to claim 4, wherein
the plurality of semiconductor elements includes a plurality of first semiconductor elements electrically connected to the plurality of first terminals, respectively, and a plurality of second semiconductor elements electrically connected to the plurality of second terminals, respectively, and
the plurality of first semiconductor elements are arranged closer to the side surface of the first mold package than the plurality of second semiconductor elements are, and the plurality of semiconductor elements are alternately arranged to form a staggered pattern on the lead frame in plan view.

6. The power semiconductor device according to claim 1, wherein
the plurality of terminals includes a plurality of first terminals and a plurality of second terminals,
the plurality of first terminals are arranged closer to the one side than the plurality of second terminals are in plan view, and
the second mold package has a projection between an array of the plurality of first terminals and an array of the plurality of second terminals on the front surface, extending in a direction parallel to both arrays.

7. The power semiconductor device according to claim 1, wherein
the plurality of terminals includes a plurality of first terminals and a plurality of second terminals,
the plurality of first terminals are arranged closer to the one side than the plurality of second terminals are in plan view, and
the second mold package has a recess between an array of the plurality of first terminals and an array of the plurality of second terminals on the front surface, extending in a direction parallel to both arrays.
